(19) United States
(12) Patent Application Publication
(10) Pub. No.: US 2021/0199150 A1
(43) Pub. Date: Jul. 1, 2021

(54) INSULATIVE LAYERS

(71) Applicant: Hewlett-Packard Development Company, L.P., Spring, TX (US)

(72) Inventors: Kuan-Ting Wu, Taipei City (TW); Chien Tu Cheng, Taipei City (TW); Al-Tsung LI, Taipei City (TW); Sung Hsueh Tsai, Taipei City (TW); Jamil Abdul Wakil, Spring, TX (US)

(73) Assignee: Hewlett-Packard Development Company, L.P., Spring, TX (US)

(21) Appl. No.: 17/042,997

(22) PCT Filed: Aug. 10, 2018
(86) PCT No.: PCT/US2018/046177

§ 371 Date: Sep. 29, 2020

(51) Int. Cl. F16B 33/00; G06F 1/20; G06F 1/16

(52) U.S. Cl. CPC F16B 33/004; G06F 1/1656; G06F 1/20

(57) ABSTRACT

A thermally resistant coupling device coupled to an electronic device may include a screw to threadingly engage with a boss hole formed in the electronic device and an elastic insulative layer encapsulating a portion of the screw. An electronic device may include a screw hole, an elastic insulative layer placed within the screw hole, and a screw to threadingly engage with the screw hole and elastic insulative layer.

### BACKGROUND

Operations of electronic devices such as computing devices may implement a number of hardware devices. These hardware devices, through use of electrical currents, may produce an amount of heat. By way of example, a central processing unit of a computing device may produce heat through operations conducted within the computing device.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a thermally resistive coupling device according to an example of the principles described herein.

FIG. 2 is a block diagram of an electronic device according to an example of the principles described herein.

FIG. 3 is a block diagram of an insulating system according to an example of the principles described herein.

FIG. 4 is a side cut view of an insulating system according to an example of the principles described herein.

FIG. 5 is a side cut view of an insulating system (500) according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Computing devices, during operation, produce large amounts of heat that are to be directed away from the particular heat source and dissipated into the environment. In some examples, these particular heat sources may include a central processing unit (CPU), a graphical processing unit (GPU), and chipsets, among other types of heat generating devices. This heat produced by the particular heat sources may reach temperatures of 47 degrees Celsius (about 116 degrees Fahrenheit) on the housing of computing devices. Without out proper heat dissipation devices, these temperatures may harm a user of the computing device.

Effects of the heat produced may be further exasperated when the computing device is a laptop device. Because users may place the laptop on a lap in order to interact with the laptop computing device, heat may be transferred from the laptop computing device to the user and more particularly to a user's skin. Where the temperature of above 45 degrees Celsius can cause burning of the skin, operation of the computing device at temperatures at or near 47 degrees is potentially dangerous.

Even still, some laptop devices may include a number of screws that help to hold the housing of the laptop device to specific hardware within the laptop device. Indeed, in these examples, some screws may couple one of the CPU, GPU, and/or chipsets directly to a portion of the housing where a user may be able to touch. These screws act as a heat sink allowing heat from the heat producing devices within the computing device to be directed away from those devices within. Whether intentional or not, these screws may become intolerably hot to the touch and may cause harm to a user.

The present specification describes a thermally resistant coupling device coupled to an electronic device that includes a screw to threadingly engage with a boss hole formed in the electronic device and an elastic insulative layer encapsulating a portion of the screw.

The present specification further describes an electronic device that includes a screw hole, an elastic insulative layer placed within the screw hole, and a screw to threadingly engage with the screw hole and elastic insulative layer.

The present specification also describes an insulating system the includes an insulative coating placed around a screw and an insulative layer formed within a screw hole formed within a surface of a computing device.

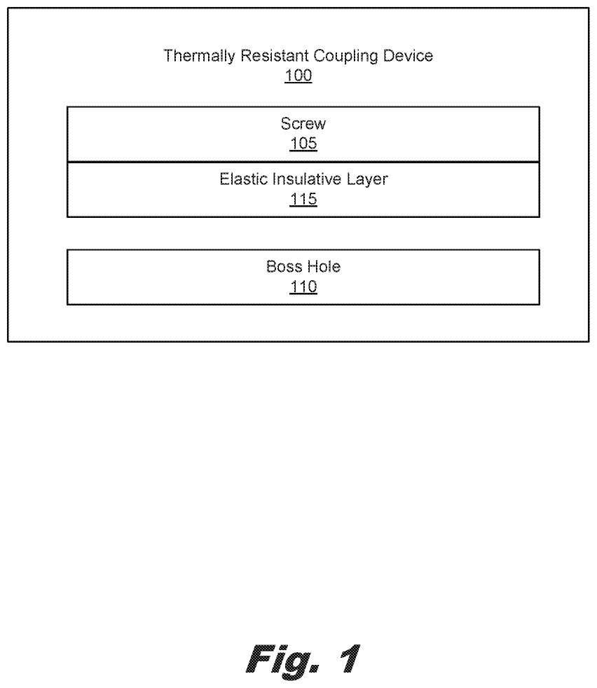

Turning now to the figures, FIG. 1 is a block diagram of a thermally resistive coupling device (100) according to an example of the principles described herein. The thermally resistive coupling device (100) may include a screw (105) to threadingly engage with a boss hole (110) formed into an electronic device. In any example presented herein, a portion of the screw (105) may be encapsulated with an elastic insulative layer (115).

The screw (105) may be any type of screw that may be coupled to a surface of an electronic device via, for example, a boss hole or screw hole. In an example, the screw may be passed through a surface of the electronic device and further couple to or otherwise engage with a number of components of the electronic device. In the example where the electronic device is a computing device, the screw (105) may pass through a surface of the computing device and couple a CPU, GPU, chipset or other hardware to the body of the computing device. In any example, however, the components of the electronic device are those components that create heat through their use of electrical currents. These heat-creating components of the electronic device may create sufficient heat to cause burns to form on a user if the heat is not dissipated. In some examples, heat sinks may be used.

However, the heat transferred to the heat sink may not be complete and instead may heat other components such as the screws and fasteners holding the heat-creating device to the housing of the electronic device. The described elastic insulative layer (115) encapsulating a portion of the screw (105) prevents such heat from being dissipated through the screw (105). It does this by placing, within the boss hole, an insulative layer between the heat-creating components of the electronic device and the screw (105) itself. Thus, the heat is not transferred to the screw and those screw portions that may come in physical contact with a user will not cause the burns described herein.

The boss hole (110) may be any type of threaded or bored hole formed within a surface of the electronic device. The boss hole (110) may be provided so as to allow the screw (105) to pass therethrough and couple a heat-creating component of the electronic device to the housing of the electronic device.

The elastic insulative layer (115) may be any type of layer that may be coated onto the surface of the screw (105) prior to engagement of the screw (105) with the boss hole (110). In the present specification and in the appended claims, the a “thermally insulative” material is meant to be understood as any material that may prevent the passage of heat from a heat-creating element to another element. In any example presented herein, the elastic insulative layer (115) may also be elastic so as to deform under shear stress or other pressures. In some examples, the deformation of the elastic insulative layer (115) allows the elastic insulative layer (115) to be coated around the screw (105) while still providing an insulative layer between the screw (105) and any other component of the electronic device.

Examples of materials the elastic insulative layer (115) may be made of includes fiberglass, mineral woods, cellulose, calcium silicate, cellular glass, elastomeric foam, phenolic foam, vermiculite, polyurethane foam, polystyrene foam in elastic polymer resins, or combinations thereof. Additional chemicals or components may be added to any one or a combination of these types of materials to render the elastic insulative layer (115) more or less elastic based on the torque used to secure the screw (105) through the surface of the electronic device. In the example where, elastic polymer resins are used to coat a surface of the screw (105), the elastic polymer resin may contain 10-50% by weight insulation materials formed within the elastic polymer resin. In this example, the elastic polymer resin may form the balance of the weight of the insulative layer (115). Specific examples of elastic polymers that may be used include EPDM rubber, epichlorohydrin rubber, polyacrylic rubber, silicone rubber, fluorosilicone rubber, fluoroelastomers, perfluoroelastomers, polyether block amides, chlorosulfonated polyethylene, ethylene-vinyl acetate, polysulfide rubber and thermoplastic elastomers.

The application of the elastic insulative layer (115) between the screw (105) and any surface of the electronic device and/or heat-creating devices within the electronic device prevents other components of the electronic device from failing. In addition to heat potentially burning a user's skin, the heat created may damage other devices such as batteries, liquid crystal display (LCD) panels, light-emitting diodes (LEDs), CPUs, GPUs, and chipsets among other heat sensitive components within the electronic device. This provides for a relatively longer lifespan of these devices as well as a reduction in repair costs associated with the electronic device. In the specific example where a battery is an additional component of the electronic device, the elastic insulative layer (115) may prevent heat from being dissipated towards the battery where the heat may damage or even explode it. This may prevent damage to the electronic device as well as prevent injury to a user due to the explosion that may be created. Additionally, with the reduction of heat dissipated to other components of the electronic device, the information loading speed and power efficiency of the components may be improved. Indeed, heat may prevent, in a data storage device, CPU, and/or GPU the proper transfer or efficient transfer of data to and from these devices. By preventing the heat from dissipating to these devices via the elastic insulative layer (115), the performance of the electronic device may be improved.

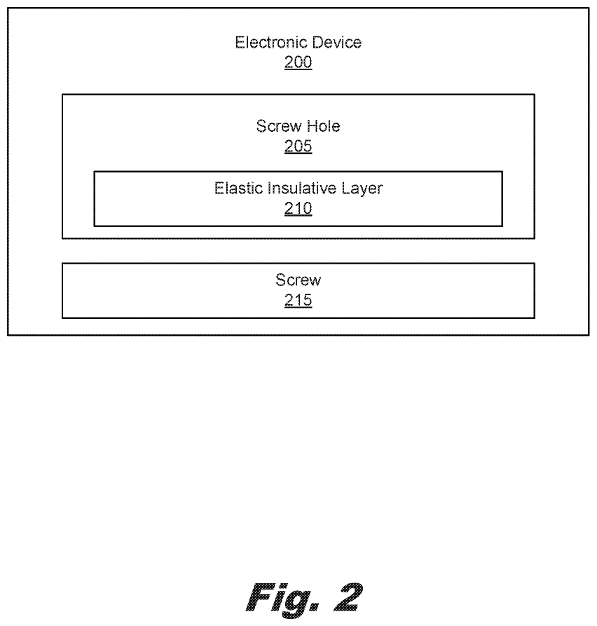

FIG. 2 is a block diagram of an electronic device (200) according to an example of the principles described herein. The electronic device (200) may include, in an example, a screw hole (205). The screw hole (205) may include an elastic insulative layer (210) placed therein. In an example, the elastic insulative layer (210) may be layered on an interior surface of the screw hole (205) formed within a surface of the electronic device.

The electronic device (200) may further include a screw (215) to threadingly engage with the screw hole (205) and elastic insulative layer (210). In an example, the insertion or engagement of the screw (215) into the screw hole (205) causes the elastic insulative layer (210) to deform to a certain degree thereby forming a tight fit between the screw (215) and the surface of the electronic device (200).

The elastic insulative layer (210) may be made of any material the provides an insulative function between the screw (215) and screw hole (205). Example materials may include fiberglass, mineral woods, cellulose, calcium silicate, cellular glass, elastomeric foam, phenolic foam, vermiculite, polyurethane foam, polystyrene foam in elastic polymer resins, or combinations thereof. Additional chemicals or components may be added to any one or a combination of these types of materials to render the elastic insulative layer (210) more or less elastic based on the torque used to secure the screw (215) through the surface of the electronic device (200). In the example where, elastic polymer resins are used to coat a surface of the screw (105), the elastic polymer resin may contain 10-50% by weight insulation materials formed within the elastic polymer resin. In this example, the elastic polymer resin may form the balance of the weight of the insulative layer (210). Specific examples of elastic polymers that may be used include EPDM rubber, epichlorohydrin rubber, polyacrylic rubber, silicone rubber, fluorosilicone rubber, fluoroelastomers, perfluoroelastomers, polyether block amides, chlorosulfonated polyethylene, ethylene-vinyl acetate, polysulfide rubber and thermoplastic elastomers. In an example, the thickness of the elastic insulative layer may be between about 25 to about 100 μm. In an example, the thickness of the elastic insulative layer may be between about 50 to about 75 μm. In an example, the thickness of the elastic insulative layer may be between about 60 to about 65 μm.

In any example presented herein, the screw (215) may include a shaft portion used to interface with the screw hole (205) and a head used to secure the screw (215) to the surface of the electronic device (200). In this example, the elastic insulative layer (210) may cover the entire shaft of the screw (215) including a terminal end of the screw (215) opposite the head of the screw (215). In this example, the elastic insulative layer (210) may be placed intermittent to any other surface of either a housing of the electronic device (200) or interfaces of the components of the electronic device (200). Again, this insulative feature of the elastic insulative layer (210) prevents damage to the components of the electronic device (200) as well as injury to a user as described herein.

In an example, the screw hole (205) formed into a surface of the electronic device (200) may have a recessed portion that allows a head of the screw (215) to fit therein. This may be done so as to cause the head of the screw (215) to be flush with a surface of the electronic device (200) when fully engaged in the screw hole (205). Additionally, because the elastic insulative layer (210) is deformable, the head of the screw (215) being secured into the recessed portion preventing any of the elastic insulative layer (210) on the screw (215) or within the screw hole (205) to be formed out of the screw hole (205).

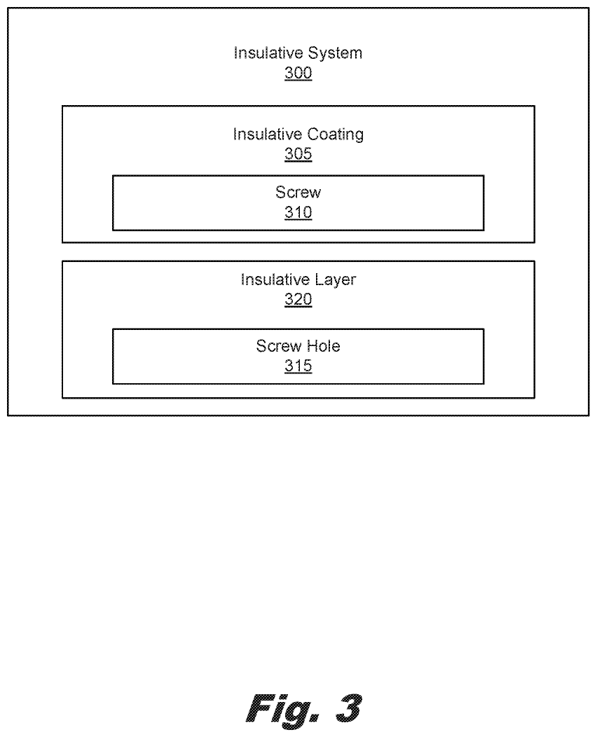

FIG. 3 is a block diagram of an insulating system (300) according to an example of the principles described herein. The insulating system (300) may include an insulative coating (305) placed around a screw (310). The insulating system (300) may further include an insulative layer (320) formed within a screw hole (315) formed within a surface of a computing device. The insulative coating (305) may be secured to the screw (310) using an adhesive, for example. This prevents the insulative coating from falling away from the screw (310). The insulative layer (320) may also be secured to an inner wall of the screw hole (315) using an adhesive. In an example, the thickness of the elastic insulative layer (320) and/or the insulative coating (305) may be between about 25 to about 100 pm. In an example, the thickness of the elastic insulative layer (320) and/or the insulative coating (305) may be between about 50 to about 75 μm. In an example, the thickness of the elastic insulative layer (320) and/or the insulative coating (305) may be between about 60 to about 65 μm.

In this example, the insulative layer (320) and the insulative coating (305) may form a tight fit between the screw (310) and screw hole (315) surface as the screw (310) is engaged with the screw hole (315) during an assembly process. Because the insulative layer (320) and insulative coating (305) are deformable, the two layers may press against each other during assembly such that a tight insulative layer is formed between the screw (310) and screw hole (315) with minimal locations along the shaft of the screw (310) and the side of the screw hole (315) being void of insulative layer (320) or insulative coating (305). In an example, threads of the screw (310), when engaging with the screw hole (315), may cut through one or both of the insulative layer (320) and the insulative coating (305). In this example, the two layers may be secured to each other while also allowing the threads of the screw (310) to engage with a wall of the screw hole (315).

In an example the insulative coating (305) and/or insulative layer (320) may be made of an elastic insulative material. As described herein, these materials may include fiberglass, mineral woods, cellulose, calcium silicate, cellular glass, elastomeric foam, phenolic foam, vermiculite, polyurethane foam, polystyrene foam in elastic polymer resins, or combinations thereof. Additional chemicals or components may be added to any one or a combination of these types of materials to render the insulative layer (320) and/or insulative coating (305) more or less elastic based on the torque used to secure the screw (310) through the surface of the computing device. In the example where, elastic polymer resins are used to coat a surface of the screw (310) and/or the screw hole (315), the elastic polymer resin may contain 10-50% by weight insulation materials formed within the elastic polymer resin. In this example, the elastic polymer resin may form the balance of the weight of the insulative layer (320) and/or insulative coating (305). Specific examples of elastic polymers that may be used include EPDM rubber, epichlorohydrin rubber, polyacrylic rubber, silicone rubber, fluorosilicone rubber, fluoroelastomers, perfluoroelastomers, polyether block amides, chlorosulfonated polyethylene, ethylene-vinyl acetate, polysulfide rubber and thermoplastic elastomers.

Application of the insulative coating (305) to the screw (310), in an example, may be accomplished by dipping the screw (310) into a liquid form of the insulative coating and allowing the coating to cure thereon. Application of the insulative layer (320) may, in an example, be accomplished by dripping a liquid form of the insulative material into the screw hole (315) and allowing the material to cure.

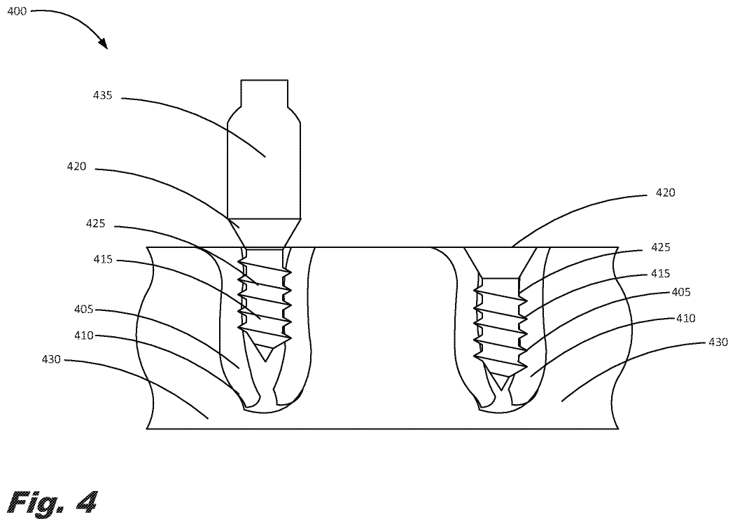

FIG. 4 is a side cut view of an insulating system (400) according to an example of the principles described herein. In this example, an elastic insulative layer (405) is placed within a screw hole (410) formed within a surface (430). Placement of the elastic insulative layer (405) within the screw hole (410) may be done by painting or dripping the elastic insulative material of the elastic insulative layer (405) into the screw hole (410).

The insulating system (400) may further include a screw (415). The screw (415) may include a screw head (420) and a screw shaft (425). The screw head (420) may include an interface to interface with a screwdriver head (435) in order to cause the rotation of the screw (415) and the thereby cause the screw (415) to seat within the screw hole (410). The screw (415) may also include a number of threads to cause the screw to be seated as described.

As shown in FIG. 4, two screws (415) have been screwed into the surface (430). A first screw (415) has been seated entirely into the screw hole (410) with the screw head (420) of the screw (415) being flush with the surface (430). The second screw (415) is shown to be in a transitional placement with the head of the screwdriver (435) engaged with the screw (415) in seating the screw (415) in the screw hole (410). As shown, the elastic insulative layer (405) has and will encase the entirety of the screw shaft (425) once completely seated in the screw hole (410). Further, the screw head (420) may prevent the elastic insulative layer (405) from being disformed beyond the surface (430) so that no elastic insulative layer (405) remains above the surface (430).

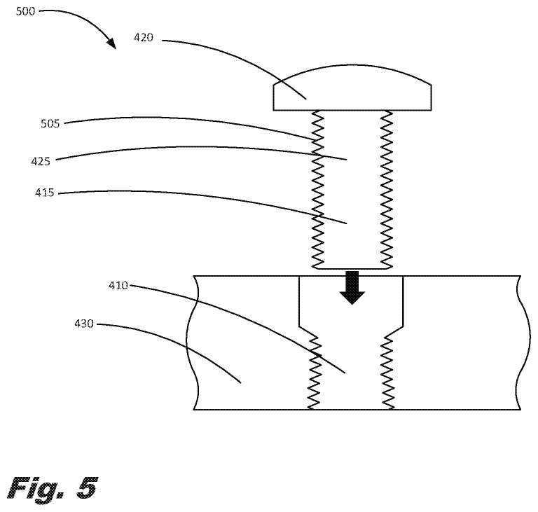

FIG. 5 is a side cut view of an insulating system (500) according to an example of the principles described herein. In this example, instead of there being an elastic insulative layer (405) formed within a screw hole (410) as depicted in FIG. 4, the screw (415) is encased in a coating of elastic insulative material (505). In this example, the coating of elastic insulative material (505) is placed in between the screw (415) and screw hole (410) as the screw (415) is sunk into the screw hole (410) by a screwdriver (435).

The present elastic insulative layer and/or coating prevents damage from occurring to other parts of the electronic device. Instead of allowing heat to be transmitted through the screw and to an LCD, CPU, GPU, and/or chipset within the computing device, the insulative layer prevents such transmission. This may prevent permanent damage to those components while also preventing injury to a user should the user touch an otherwise hot screw.

The preceding description has been presented to illustrate and describe examples of the principles described. This description is not intended to be exhaustive or to limit these principles to any precise form disclosed. Many modifications and variations are possible in light of the above teaching.

What is claimed is:

1. A thermally resistant coupling device coupled to an electronic device, the thermally resistant coupling device comprising:
a screw to threadingly engage with a boss hole formed in the electronic device; and
an elastic insulative layer encapsulating a portion of the screw.

2. The thermally resistant coupling device of claim 1, wherein the thickness of the elastic insulative layer is about 25 to about 100 μm.

3. The thermally resistant coupling device of claim 1, wherein the boss hole comprises threads on an interior surface to receive the screw and wherein the elastic insulative layer spreads within the threads as the screw engages the boss hole.

4. The thermally resistant coupling device of claim 1, wherein the elastic insulative layer comprises fiberglass, mineral woods, cellulose, calcium silicate, cellular glass, elastomeric foam, phenolic foam, vermiculite, polyurethane foam, polystyrene foam in elastic polymer resins, or combinations thereof.

5. The thermally resistant coupling device of claim 1, comprising a layer of elastic insulative layer on an interior surface of the boss hole.

6. The thermally resistant coupling device of claim 1, wherein a portion of the screw seals the elastic insulative layer into the boss hole when coupled within the boss hole.

7. The thermally resistant coupling device of claim 1, wherein the elastic insulative layer and the screw, when engaged within the boss hole, sits flush with a surface of the electronic device.

8. An electronic device, comprising:
a screw hole;
an elastic insulative layer placed within the screw hole; and
a screw to threadingly engage with the screw hole and elastic insulative layer.

9. The electronic device of claim 8, wherein the thickness of the elastic insulative layer is about 25 to about 100 μm.

10. The electronic device of claim 8, wherein the screw comprises an elastic insulation coating that interfaces with the elastic insulative layer placed within the screw hole.

11. The electronic device of claim 10, wherein the elastic insulation coating and the elastic insulative layer placed within the screw hole merge when the screw is threadingly engaged with the screw hole.

12. The electronic device of claim 8, wherein the elastic insulative layer comprises fiberglass, mineral woods, cellulose, calcium silicate, cellular glass, elastomeric foam, phenolic foam, vermiculite, polyurethane foam, polystyrene foam in elastic polymer resins, or combinations thereof.

13. The electronic device of claim 8, comprising a recess formed into a surface of the electronic device into which the insulative layer and the screw, when engaged with the electronic device, are placed so as to sit flush with a surface of the electronic device sealing the insulative layer within the screw hole.

14. An insulating system, comprising:
an insulative coating placed around a screw; and
an insulative layer formed within a screw hole formed within a surface of a computing device.

15. The insulating system of claim 14, wherein engagement of the screw with the screw hole combines the insulative coating and insulative layer and seals the insulative layer and insulative coating within the screw hole.
